(19) United States
(12) Patent Application Publication
(10) Pub. No.: US 2012/0104544 A1
(43) Pub. Date: May 3, 2012

(54) SEMICONDUCTOR DEVICE

(75) Inventor: Yoshitaka KUBOTA, Kanagawa (JP)

(73) Assignee: RENESAS ELECTRONICS CORPORATION, Kawasaki-shi (JP)

(21) Appl. No.: 13/274,976

(22) Filed: Oct. 17, 2011

(30) Foreign Application Priority Data
Nov. 2, 2010 (JP) 2010-245816

(51) Int. Cl. H01L 23/525

(52) U.S. Cl. 257/530; 257/E23.147

(57) ABSTRACT

A semiconductor device adapted such that written information cannot be analyzed even by using a method of analyzing the presence or absence of electric charge, accumulated on a gate electrode, in which a substrate is a first conduction type, for example, p-type semiconductor substrate (for example, silicon substrate), an antifuse has a gate electrode and a second conduction type diffusion layer, the second conduction type diffusion layer is formed in the substrate and has, for example, an n-conduction type, a first contact is connected to the gate electrode, second contacts are formed in a layer identical with the first contact and connected to a region of the substrate in which the second conduction type diffusion layer is not formed, and the second contact is adjacent to the first contact.

### CROSS-REFERENCE TO RELATED APPLICATIONS

The disclosure of Japanese Patent Application No. 2010-245816 filed on Nov. 2, 2010 including the specification, drawings and abstract is incorporated herein by reference in its entirety.

### BACKGROUND

The present invention concerns a semiconductor device having an antifuse as a memory device.

Memory devices include a not rewritable non-volatile memory device (one time programmable device (OTP)). As the OTP device, a memory device in which a fuse formed of a material identical with that of a gate electrode (for example, polysilicon) or a material identical with that of wirings (for example, Cu or Al) is disconnected by electromigration or fusing has been known generally.

In recent years, it has also been demanded for the OTP device that written information cannot be analyzed easily. A memory device of a fuse disconnection type involves a problem that written information can be analyzed since the presence or absence of disconnection can be analyzed easily by image processing or the like as shown, for example, by Greg Uhlmann, et al., in “A Commercial Field-Programmable Dense eFUSE Array Memory with 99.999% Sense Yield for 45 nm SOI CMOS”, 2008 IEEE INTERNATIONAL SOLID-STATE CIRCUITS CONFERENCE, SESSION 22, 22.4.

In recent years, an antifuse type memory device has been developed as the OTP device. The antifuse type memory device is adapted to apply a voltage higher than a breakdown voltage to a gate insulating film or a dielectric film of an MIM capacitor to cause dielectric breakdown thereby writing information (for example, refer to JP No. 4410101 and JP-A-2009-290189). In the antifuse type memory device of breaking down the gate insulating film, when the insulating film is broken down while selecting appropriate conditions, it is difficult to analyze the breakdown portion by image processing or the like.

### SUMMARY

Also in the antifuse type memory device, the written information can be analyzed by using a method, for example, a voltage contrast method of analyzing the presence or absence of charge accumulation on an electrode (for example, gate electrode). The reason is as described below. In a state where the dielectric film (for example, gate insulating film) is not broken down, when electric charges are irradiated to wirings connected to the electrode, the electric charges are accumulated on the electrode. On the other hand, in a state where the dielectric film is broken down, even when electric charges are irradiated to the wirings connected to the electrodes, the electric charges are released by way of the dielectric film to an underlayer (for example, a substrate). Accordingly, written information can be analyzed by using the method of analyzing the presence or absence of charge accumulation on the electrode.

According to an aspect of the present invention, there is provided a semiconductor device including a first conduction type substrate, an antifuse having a second conduction type diffusion layer formed in the substrate and a gate electrode, a first contact connected to the gate electrode, and a second contact formed in a layer identical with the first contact and connected to a region of the substrate not formed with the second conduction type diffusion layer, in which the first contact and the second contact are adjacent but spaced apart with each other.

When the presence or absence of charges accumulated on the electrode is analyzed in the antifuse type memory device, analysis is often performed by the following procedures. At first, electric charges are irradiated after removing a portion of a multi-layered wiring layer above the gate electrode, that is, a portion above the first layer of the wiring layer, and then image is taken up by an electron microscope. Then, in the obtained image, brightness at the contact connected with the gate electrode and the periphery thereof is discriminated. When the gate electrode of the antifuse is in electric conduction with the substrate, since the electric charges are not accumulated on the gate electrode and the contact, the contact and the periphery thereof become dark. On the other hand, when the gate electrode of the antifuse is not in electric conduction with the substrate, since electric charges are accumulated on the gate electrode and the contact, the contact and the periphery thereof become bright.

Then, since the second contacts in the invention are connected to a region of the substrate in which the second conduction type diffusion layer is not formed, electric charges are not accumulated even when the electric charges are irradiated. Therefore, in the image obtained by the electron microscope, the second contacts and the periphery thereof become dark. Further, the second contacts are adjacent to the first contact. Accordingly, in the image obtained by the electron microscope, the first contact and the periphery thereof are always dark irrespective of presence or absence electric conduction between the gate electrode and the substrate. Accordingly, the written information cannot be analyzed even by using a method of analyzing the presence or absence of charge accumulation on the gate electrode.

According to the aspects of the present invention, there can be provided a semiconductor device in which written image cannot be analyzed even by using the method of analyzing the presence or absence of charge accumulation on the gate electrode.

### DETAILED DESCRIPTION OF THE DRAWINGS

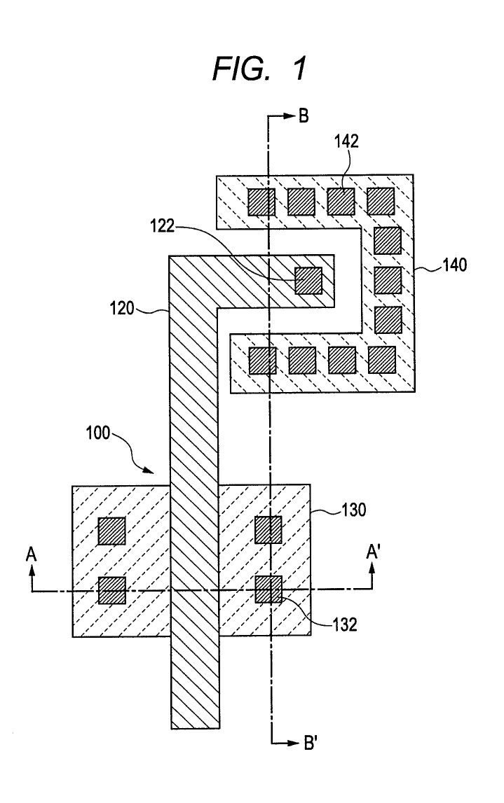

FIG. 1 is a plan view showing the configuration of a semiconductor device according to a first embodiment;

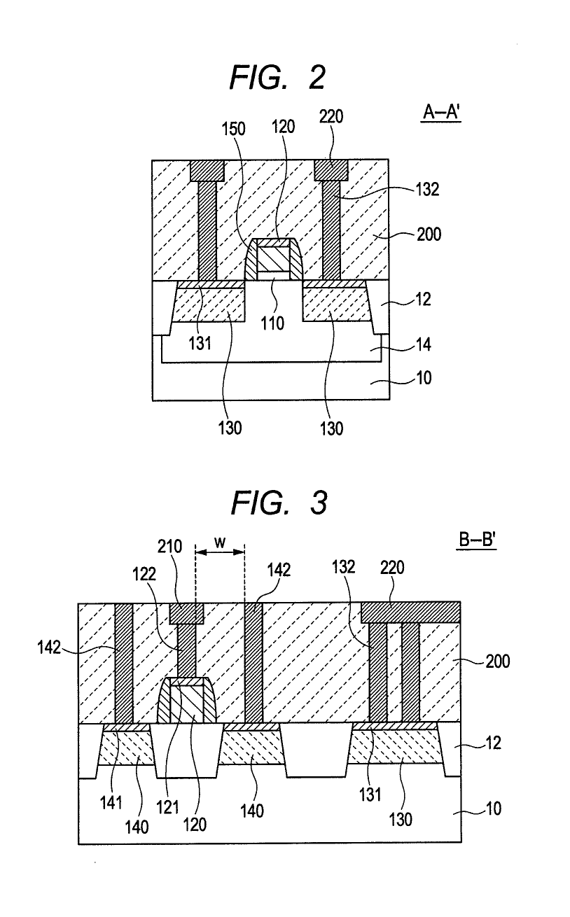

FIG. 2 is a cross sectional view along line A-A′ in FIG. 1;

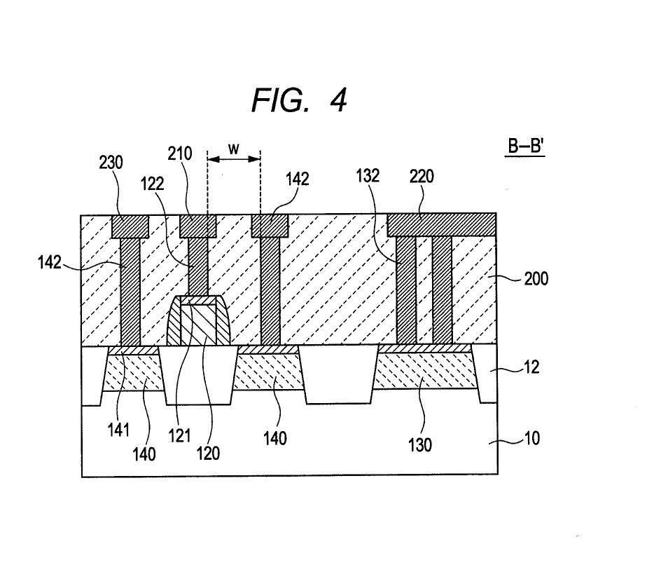

FIG. 3 is a cross sectional view along line B-B′ in FIG. 1;

FIG. 4 is a cross sectional view showing the configuration of a semiconductor device according to a second embodiment;

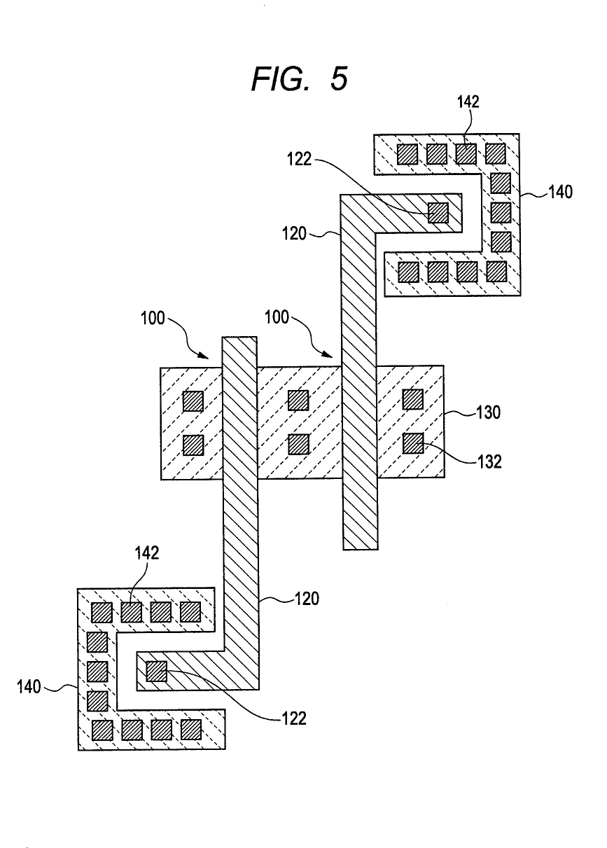

FIG. 5 is a plan view showing the configuration of a semiconductor device according to a third embodiment;

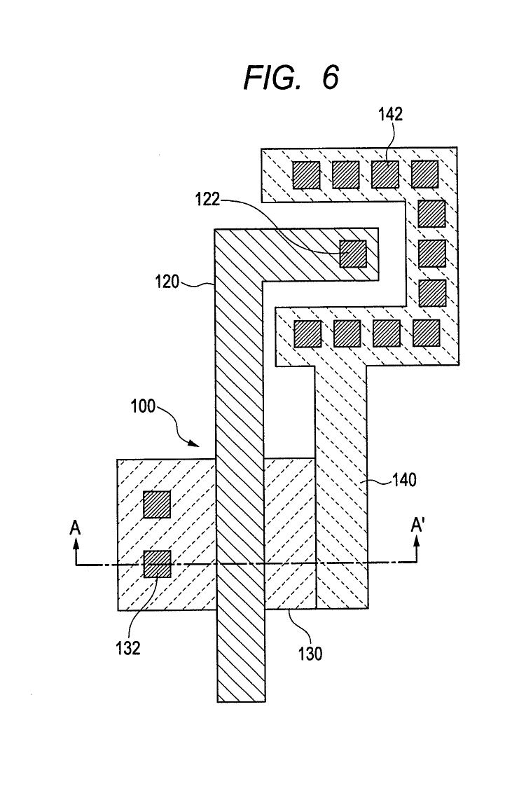

FIG. 6 is a plan view showing the configuration of a semiconductor device according to a fourth embodiment;

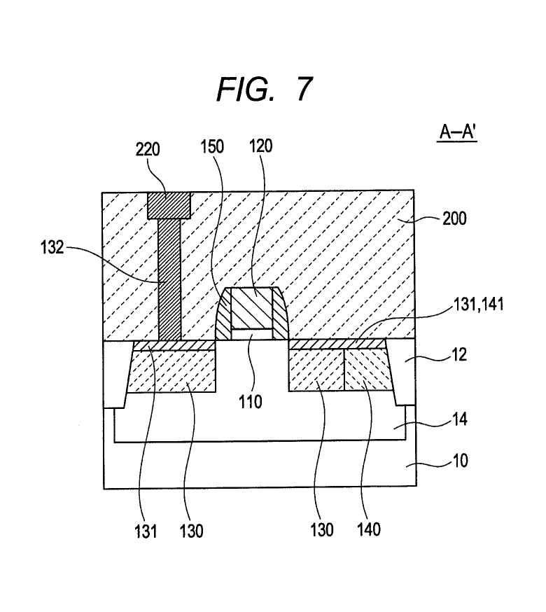

FIG. 7 is a cross sectional view along line A-A′ in FIG. 6;

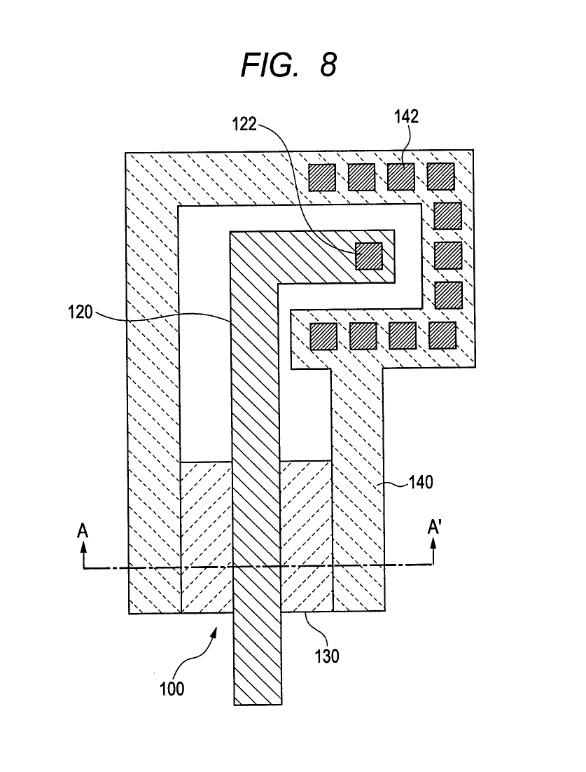

FIG. 8 is a plan view showing the configuration of a semiconductor device according to a fifth embodiment;

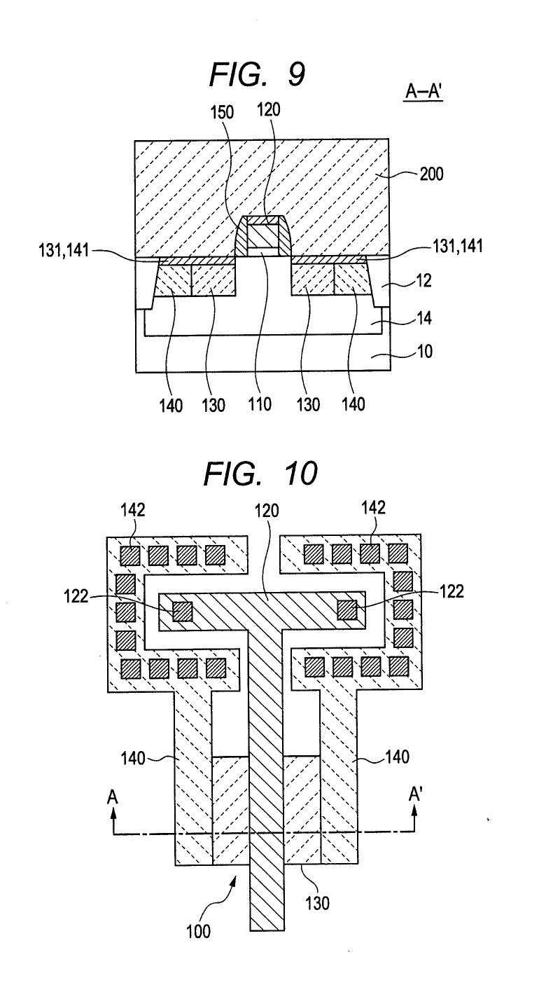

FIG. 9 is a cross sectional view along line A-A′ in FIG. 8;

FIG. 10 is a plan view showing the configuration of a semiconductor device according to a sixth embodiment;

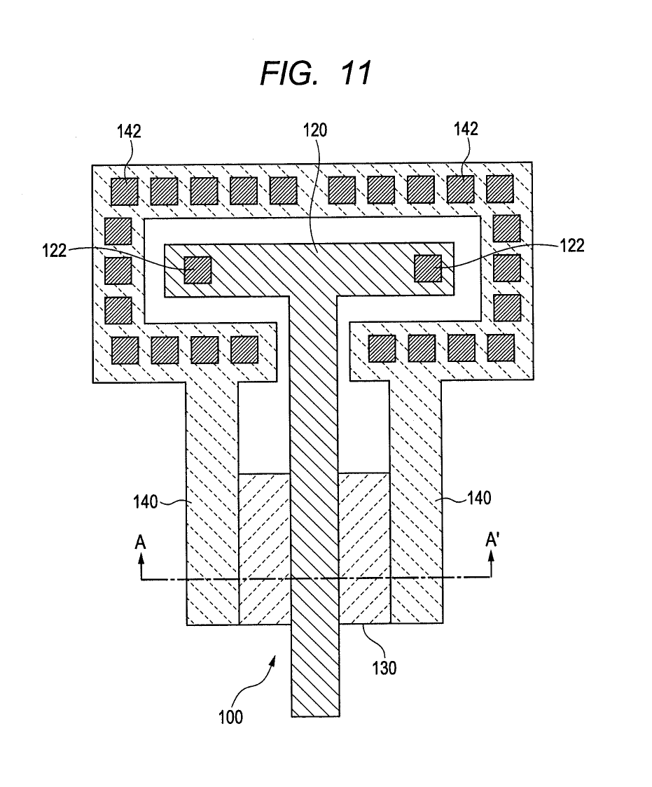

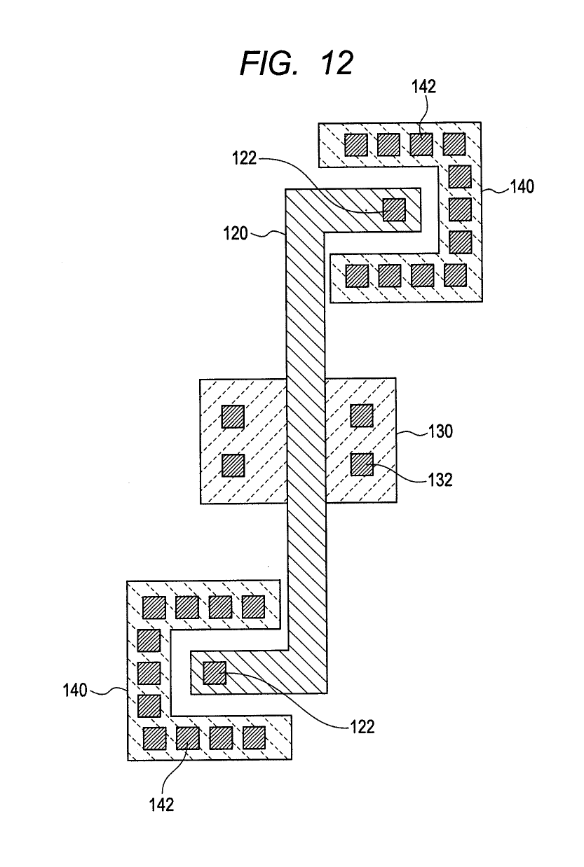

FIG. 11 is a plan view showing the configuration of a semiconductor device according to a seventh embodiment; and

FIG. 12 is a plan view showing the configuration of a semiconductor device according to an eighth embodiment.

### DETAILED DESCRIPTION

The present invention is to be described by way of preferred embodiments with reference to the drawings. Throughout the drawings, identical constitutional elements carry same reference numerals for which explanations are to be omitted optionally.

### First Embodiment

FIG. 1 is a plan view showing the configuration of a semiconductor device according to a first embodiment. FIG. 2 is a cross sectional view along line A-A′ in FIG. 1, and FIG. 3 is a cross sectional view along line B-B′ in FIG. 1. The semiconductor device according to this embodiment has a substrate 10, an antifuse 100, a first contact 122, and second contacts 142. The substrate 10 is a first conduction type, for example, a p-type semiconductor substrate (for example, silicon substrate). The antifuse 100 has a gate electrode 120 and a second conduction type diffusion layer 130. The antifuse 100 has a gate electrode 120 and a second conduction type diffusion layer 130. The second conduction type diffusion layer 130 is formed in the substrate 10 and has, for example, an n-conduction type. The first contact 122 is connected with the gate electrode 120. The second contacts 142 are formed in a layer identical with the first contact 122 and connected in a region of the substrate 10 in which the second conduction type diffusion layer 130 is not formed. The second contacts 142 are adjacent to the first contact 122. However, the second contacts 142 are spaced from the first contact 122. They are to be described more specifically.

The substrate 10 has a second conduction type well 14. The antifuse 100 is formed in the well 14. The antifuse 100 has a configuration, for example, identical with that of a MOS transistor or a MOS capacitor and has a configuration in which the gate electrode 120 is stacked on a gate insulating film 110 and, further, a second conduction type diffusion layer 130 is disposed on both sides of the gate electrode 120 in a plan view. The gate insulating film 110 is, for example, a silicon oxide film and the film thickness is, for example, 3 nm or less. A side wall 150 is formed on the side wall of the gate electrode 120. A ground potential is applied by way of the contact 132 to the second conduction type diffusion layer 130. However, the antifuse 100 is not restricted to the configuration described above.

Also, the first conduction type may be an n-type and the second conduction type may be a p-type. In this case, a power source potential is applied by way of the contacts 132 to the second conduction type diffusion layer 130.

As described above, the second contacts 142 are adjacent to but not in contact with the first contact 122. As shown in FIG. 3, the space w between the first contact 122 and the second contact 142 is 0.5 μm or less and, preferably, 0.2 μm or less.

More specifically, the first contact 122 is connected to a portion of the gate electrode 120 situated above a device isolation film 12, for example, at the end of the gate electrode 120. In this embodiment, while the gate electrode 120 extends linearly at a portion situated above the gate insulating film 110 and the periphery thereof, it is bent by a right angle at the end on the side connected to the first contact 122. Then, the second contacts 142 are formed in plurality at a position sandwiching the gate electrode 120 and the first contact 122. Specifically, the second contacts 142 are disposed along three sides of a rectangular or square shape so as to surround a right angled portion of the gate electrode 120 while dodging the gate electrode 120. None of wirings is connected to the second contacts 142. That is, the second contacts 142 are in a floating state except that they are connected to the first conduction type diffusion layer 140.

Further, a multi-layered wiring layer is formed above the gate insulating film 110. In FIG. 2 and FIG. 3, only the interlayer dielectric film at the lowermost layer (including the wiring layer insulating film 200) is shown. A signal wiring 210 and a wiring 220 are formed to the surface layer of the interlayer dielectric film 200. The signal wiring 210 is connected to the gate electrode 120 by way of the first contact 122 and inputs a writing signal or a reading voltage to the gate electrode 120. The wiring 220 is connected to the second conduction type diffusion layer 130 by way of the contacts 132 and applies a ground potential to the second conduction type diffusion layer 130.

A first conduction type diffusion layer 140 is formed in the substrate 10. The first conduction type diffusion layer 140 is situated below a region in which the second contacts 142 are formed and connected to the second contacts 142. The impurity concentration in the first conduction type diffusion layer 140 is higher than that of the well 14. In the embodiment shown in FIG. 1, the first conduction type diffusion layer 140 is disposed along three sides of a rectangular or square shape so as to surround a portion of the gate electrode 120 that is bent by the right angle while dodging the gate electrode 120.

Further, device isolation films 12 are formed in the substrate 10. The device isolation films 12 isolate the regions of the antifuse 100 in which the gate insulating film 110 and the second conduction type diffusion layer 130 are formed from other regions, for example, the first conduction type diffusion layer 140.

Silicide layers 121, 131, and 141 are formed at the surface of the gate electrode 120, the second conduction type diffusion layer 130, and the first conduction type diffusion layer 140. The silicide layers 121, 131, and 141 are formed, for example, of Ni silicide.

Then, the function and the effect of this embodiment are to be described. When presence or absence of charge accumulation on the gate electrode 120 is analyzed in the antifuse 100, it is often analyzed by the following procedures. At first, in the multi-layered wiring layer above the gate electrode 120, a portion above the first contact 122, the contacts 132, and the second contacts 142, that is, the portion above the first layer of the wiring layer is removed. In this step, the first contact 122, the contacts 132, and the second contacts 142 may be removed as far as the midway portion. Then, electric charges are irradiated to the first contact 122, the contacts 132, and the second contacts 142, and their images are taken up by an electrode microscope. Then, the obtained image is analyzed to discriminate the brightness of the first contact 122 connected to the gate electrode 120 and the periphery thereof. When the gate electrode 120 of the antifuse 100 is in electric conduction with the substrate 10, since electric charges are not accumulated on the gate electrode 120 and the first contact 122, the first contact 122 and the periphery thereof become dark. On the other hand, when the gate electrode 120 of the antifuse 100 is not in electric conduction with the substrate 10, since the electric charges are accumulated on the gate electrode 120 and the first contact 122, the first contact 122 and the periphery thereof become bright.

On the contrary, in this embodiment, since the second contacts 142 are connected to the region of the substrate 10 in which the second conduction type diffusion layer 130 is not formed and, accordingly, electric charges are released to the substrate 10 even when the electric charges are irradiated, and they are not accumulated. Therefore, in the image obtained by the electron microscope, the second contacts 142 and the periphery thereof become dark. Further, the second contacts 142 are adjacent to the first contact 122. Accordingly, in the image obtained by the electron microscope, the first contact 122 and the periphery thereof are always dark irrespective of electric conduction between the gate electrode 120 and the substrate 10. Therefore, written information cannot be analyzed even by using the method of analyzing the presence or absence of charge accumulation on the gate electrode 120. The effect becomes remarkable when the space w between the first contact 122 and the second contact 142 is 0.5 μm or less and becomes particularly remarkable when the space w is 0.2 μm or less. Further, in this embodiment, since the second contacts 142 are formed so as to sandwich the first contact 122, the effect described above becomes remarkable.

Further, in this embodiment, since the second contacts 142 are connected to the first conduction type diffusion layer 140, electric charges irradiated to the second contacts 142 tend to release to the first conduction type diffusion layer 140. Therefore, in the image obtained by the electron microscope, since the second contacts 142 and the periphery thereof become dark particularly, the effect described above becomes remarkable.

Further, since the second contacts 142 are connected to none of the wirings in the multi-layered wiring layer, provision of the second contact 142 gives no effect on the function of the semiconductor device.

### Second Embodiment

FIG. 4 is a cross sectional view showing a configuration of a semiconductor device according to a second embodiment, which corresponds to FIG. 3 for the first embodiment. The semiconductor device according to this embodiment has a configuration identical with that of the semiconductor device according to the first embodiment except for the provision of a wiring 230.

The wiring 230 is formed in a layer identical with that of the signal wiring 210 and the wiring 220 and connected to a ground wiring (not illustrated) in a multi-layered wiring layer. The wiring 230 is connected to the first conduction type diffusion layer 140 by way of the second contacts 142, to apply a ground potential to the first conduction type diffusion layer 140.

An effect identical with that in the first embodiment can be obtained also in this embodiment.

### Third Embodiment

FIG. 5 is a plan view showing a configuration of a semiconductor device according to a third embodiment, which corresponds to FIG. 1 for the first embodiment. The semiconductor device of this embodiment has a configuration identical with that of the semiconductor device according to the first or second embodiment except for providing multiple antifuses 100.

A first contact 122 is disposed to each of the antifuses 100. Then, multiple second contacts 142 are disposed for each of the multiple first contacts 122.

An effect identical with that in the first embodiment can be obtained also in this embodiment.

### Fourth Embodiment

FIG. 6 is a plan view showing a configuration of a semiconductor device according to a fourth embodiment, which corresponds to FIG. 1 for the first embodiment. FIG. 7 is a cross sectional view along line A-A′ in FIG. 6, which corresponds to FIG. 2 for the first embodiment. The semiconductor device according to this embodiment is identical with that of the second embodiment except for the following points.

At first, a first conduction type diffusion layer 140 has a portion extending from a region in which second contacts 142 are formed to a second conduction type diffusion layer 130 in a plan view, and the extending portion is connected to one of the second conduction type diffusion layers 130. That is, one of the second conduction type diffusion layers 130 forms a butting diffusion with the second contact 142. Then, silicide layers 131, 141 are formed integrally at the surface layer of the second conduction type diffusion layer 130 and the first conduction type diffusion layer 140. That is, the second conduction type diffusion layer 130 is connected to the second contacts 142 by way of the silicide layers 131 and 141. Therefore, a ground potential is applied to the second conduction type diffusion layer 130 by way of the second contacts 142 and the silicide layers 131, 141. Therefore, it is not necessary to form the contact 132 in the second conduction type diffusion layer 130 connected with the first conduction type diffusion layer 140.

An effect identical with that in the second embodiment can be obtained also in this embodiment. Further, since it is not necessary to form the contacts 132 to one side of the second conduction type diffusion layer 130, a region for extending around the wiring 220 thereto is narrowed correspondingly. Accordingly, the degree of freedom for the design of the wiring layer including the signal wiring 210 and the wiring 220 is improved.

### Fifth Embodiment

FIG. 8 is a plan view showing a configuration of a semiconductor device according to a fifth embodiment, which corresponds to FIG. 6 for the fourth embodiment. FIG. 9 is a cross sectional view along line A-A′ in FIG. 8, which correspond to FIG. 7 for the fourth embodiment. The semiconductor device according to this embodiment has a configuration identical with that of the fourth embodiment except for the following points.

At first, the planar shape of the first conduction type diffusion layer 140 is different. Specifically, the first conduction type diffusion layer 140 is connected to both of the second conduction type diffusion layers 130. Therefore, a ground potential is applied to both of the second conduction type diffusion layers 130 by way of the silicides 141, 131. Then, contacts 132 are formed to none of the second conduction type diffusion layers 130.

Since two gate electrodes 120 are in a short-circuited form in this embodiment, the antifuse 100 has a structure like a MOS capacitor.

An effect identical with that in the fourth embodiment can be obtained also in this embodiment. Further, since it is not necessary to form the contact 132 to any of the second conduction type diffusion layers 130, the region of extending around the wiring 220 is further narrowed correspondingly. Accordingly, the degree of freedom for the design of the wiring layer including the signal wiring 210 and the wiring 220 is further improved.

### Sixth Embodiment

FIG. 10 is a plan view showing a configuration of a semiconductor device according to a sixth embodiment, which corresponds to FIG. 6 for the fourth embodiment. The semiconductor device according to this embodiment is identical with the fourth embodiment except for the following points.

At first, a gate electrode 120 is branched at the end on the side having first contacts 122. In the embodiment shown in this drawing, the gate electrode 120 has a substantially T-shaped form. Then, the first contacts 122 are disposed at respective branched ends of the gate electrode 120.

The second contacts 142 and the first conduction type diffusion layer 140 are disposed to each of the first contacts 122. Then, two first conduction type diffusion layers 140 are connected to second conduction type diffusion layers 130 different from each other. Then, a ground potential is applied to each of the second conduction type diffusion layers 130 by way of silicides 141, 131. Accordingly, it is not necessary to form contacts 132 to any of the second conduction type diffusion layers 130.

An effect identical with that in the fourth embodiment can be obtained also in this embodiment. Further, since it is not necessary to form the contact 132 to any of the second conduction type diffusion layers 130, the region of extending around the wiring 220 may be narrowed further correspondingly. Accordingly, the degree of freedom for the design of the wiring layer including the signal wiring 210 and the wiring 220 is further improved.

### Seventh Embodiment

FIG. 11 is a plan view showing a configuration of a semiconductor device according to a seventh embodiment, which corresponds to FIG. 10 for the sixth embodiment. The semiconductor device according to this embodiment has a configuration identical with that of the semiconductor device according to the sixth embodiment except that two first conduction type diffusion layers 140 are connected to each other. That is, in this embodiment, since the two gate electrodes 120 are in a short circuited form, the antifuse 100 has a structure like a MOS capacitor.

Also in this embodiment, an effect identical with that in the sixth embodiment can be obtained. Further, since the area of the first conduction type diffusion layer 140 increases, the number of the second contacts 142 can be increased.

### Eighth Embodiment

FIG. 12 is a plan view showing a configuration of a semiconductor device according to an eighth embodiment, which corresponds to FIG. 1 for the first embodiment. The semiconductor device according to this embodiment has a configuration identical with that of the semiconductor device according to the first embodiment except for the following points.

At first, the gate electrode 120 is bent at both ends each by a right angle in directions different from each other. Then, a first contact 122, a first conduction type diffusion layer 140, and multiple second contacts 142 are disposed on both ends respectively. The planar shape of the first conduction type diffusion layer 140 and the arrangement of the second contacts 142 are identical with those in the first embodiment.

Also in this embodiment, an effect identical with that in the first embodiment can be obtained. Further, since the first contacts 122 are disposed on both ends of the gate electrode 120, there is no problem even when the amount of current flowing in the gate electrode 120 increases.

While the present invention has been described by way of preferred embodiments with reference to the drawings, they are only the examples of the invention and various other configurations than those described above can also be adopted.

What is claimed is:

1. A semiconductor device comprising:
a first conduction type substrate;
an antifuse having a second conduction type diffusion layer formed in the substrate and a gate electrode;
a first contact connected to the gate electrode;
a second contact formed in a layer identical with the first contact and connected with a region of the substrate where the second conduction type diffusion layer is not formed,
wherein the first contact and the second contact are adjacent but spaced apart with each other.

2. The semiconductor device according to claim 1, wherein the space between the first contact and the second contact is 0.5 μm or less.

3. The semiconductor device according to claim 2, wherein the space is 0.2 μm or less.

4. The semiconductor device according to claim 1,
wherein a plurality of the antifuses and the first contacts are provided, and
wherein the second contacts are disposed to the first contact respectively.

5. The semiconductor device according to claim 1, further comprising:
a first conduction type diffusion layer formed in a region of the substrate connected to the second contact and having an impurity concentration higher than that of the substrate.

6. The semiconductor device according to claim 5,
wherein the first conduction type diffusion layer and the second conduction type diffusion layer have silicide layers on the surface layers thereof, and
wherein the first conduction type diffusion layer is connected to the second conduction type diffusion layer.

7. The semiconductor device according to claim 1, wherein a plurality of the second contacts are formed at positions of sandwiching the first contact.

8. The semiconductor device according to claim 1,
wherein the first contact is connected to the end of the gate electrode, and
wherein the second contacts are arranged so as to surround the first contact while dodging the gate electrode.

9. The semiconductor device according to claim 1,
wherein a plurality of the first contacts are disposed to one gate electrode, and
wherein the second contacts are disposed to the first contacts respectively.

10. The semiconductor device according to claim 1,
wherein a multi-layered wiring layer formed over the first contact and the second contact and having a signal wiring is provided, and
wherein the second contacts are not electrically connected to the signal wiring.

11. The semiconductor device according to claim 10, wherein the multi-layered wiring layer has a ground wire and the second contact is electrically connected with the ground wire.
